(19) United States
(12) Patent Application Publication
(10) Pub. No.: US 2023/0273265 A1
(43) Pub. Date: Aug. 31, 2023

(54) METHOD FOR DETERMINING OF AT LEAST ONE CHARACTERISTIC VALUE OF A BATTERY CELL

(71) Applicant: RHEINISCH-WESTFÄLISCHE TCHINISCHE HOCHSCHULE (RWTH) AACHEN, Aachen (DE)

(72) Inventors: Weihan LI, Aachen (DE); Neil SENGUPTA, Aachen (DE); Dirk Uwe SAUER, Aachen (DE)

(21) Appl. No.: 18/040,724

(22) PCT Filed: Aug. 11, 2021
(86) PCT No.: PCT/EP2021/072331

§ 371 Date: Feb. 6, 2023

(30) Foreign Application Priority Data
Aug. 11, 2020 (LU) LU101984

(51) Int. Cl. G01R 31/392; G01R 31/367

(52) U.S. Cl. CPC G01R 31/392; G01R 31/367

(57) ABSTRACT

The invention relates to a method for locally determining at least one characteristic value of a battery cell, wherein time series of voltages and time or another measure of a state-of-health indicator of a cell are supplied to a further neural network, wherein the further neural network is a network designed for sequence-to-sequence deep learning, and for obtaining a second indicator from the further neural network, wherein the second indicator is a further measure for the expected degradation of the cell. The invention also relates to a device for carrying out the method.

### TECHNICAL FIELD

The invention relates to the field of the determination of a characteristic value of a battery cell.

### PRIOR ART

Lithium-ion batteries are now being widely used in the electromobility sector. One of the reasons for this is that the costs are low in relation to the energy storage density. Storage systems are also increasingly finding their way into the sector of decentralised energy generation. Where reference is made in what follows to lithium-based batteries, this is only by way of example.

However, it is known that electrical storage media such as lithium-ion batteries suffer a loss of performance that is a function of various factors. This loss of performance is mainly due to the storage as well as the use.

There is therefore a requirement for a way to assess the usability and reliability of such storage media in operation.

It would therefore be desirable to be able to derive the condition of the storage media from the data from a battery management system. This is of particular interest to both the current owner and also to the manufacturer.

As a measure for the ageing status of a lithium-ion battery, a so-called “state-of-health” indicator (abbreviated as SOH) is currently used. This “state-of-health” indicator can be determined on the basis of the remaining cell capacity and also the internal resistance.

Another measure is the anticipated service life, or the anticipated end-of-life (abbreviated as EOL). The end-of-life is usually defined as the point at which the state-of-health indicator arrives at, or falls below, a certain value, for example 80 % of the original value of the remaining (nominal) capacity, or 200 % of the original internal resistance. The remaining-useful-lifetime (abbreviated as RUL) corresponds to the end-of-life. The remaining-useful-lifetime indicates the time during which the cell can be operated normally.

In what follows, the presence of a remaining capacity is assumed.

The precise estimation of a “state-of-health” indicator is an essential element for the operation, maintenance, and optimisation of cells.

However, the estimation is extremely difficult, due to the complex and non-linear mechanisms that contribute to the ageing of a cell. The papers “Ageing mechanisms in lithium-ion batteries” by the authors J. Vetter, P. Noväk, M. R. Wagner, C. Veit, K.-C. Möller, J. O. Besenhard, M. Winter, M. Wohlfahrt-Mehrens, C. Vogler, A. Hammouche, published in the Journal of Power Sources 147 (1-2) (2005) 269-281, and also “Review and performance comparison of mechanical-chemical degradation models for lithium-ion batteries” by the authors J. M. Reniers, G. Mulder, D. A. Howey, published in the Journal of the Electrochemical Society 166 (14) (2019) A3189-A3200, illustrate such mechanisms, for example the definition of the interface (solid electrolyte interface), or the formation of metallic lithium (lithium plating), or the current collector degradation. In this context it should be noted that these individual ageing mechanisms are interrelated, and contribute to different modes of ageing.

The paper “Machine Learning-Based Lithium-Ion Battery Capacity Estimation Exploiting Multi-Channel Charging Profiles”, by the authors Choi Yowan et al, published in IEEE ACCESS, vol. 7, 1 Jun. 2019 (2019-06-01), pages 75143-75152, DOI: 10.1109/ACCESS.2019.2920932. is of known prior art. This paper specifies a method with which the current maximum capacity of a cell can be estimated. However, this does not provide any statement about the presumed service life of a cell.

Furthermore, the paper “State-of-charge sequence estimation of lithium-ion battery based on bidirectional long short-term memory encoder-decoder architecture” by the authors Bian Chon et al, published in the Journal of Power Sources, Elsevier SA, CH, vol. 449, 5 Dec. 2019 (2019-12-05), ISSN: 0378-7753, DOI: 10.1016/J.JPOWSOUR.2019.227558, is of known prior art. This paper specifies a method with which the current state of charge of a cell can be estimated. However, this does not provide any statement about the presumed service life of a cell.

From the prior art methods for the estimation of the SOH of a cell are of known art. In this context a controlled experimental approach is of little practical importance. Such approaches are based on charge counting (coulomb counting), electrochemical impedance spectroscopy, incremental capacity (abbreviated as IC), and differential voltage analysis (in English sources known as differential voltage, and abbreviated as DV).

These methods are characterised by the requirement for a unique current profile in the course of discharge. However, such a discharge profile is difficult to reproduce in an actual application. For example, the so-called IC/DV analysis uses charge-voltage (Q-V) curves that are obtained, for example, by means of a low current through the cell to simulate an equilibrium operation. From the curves obtained, IC and DV curves are obtained by derivation. However, the derivation process amplifies perturbations, even if these are countered by smoothing filtering. In addition, data must be collected over a wide range of voltages, which is a demanding, time-consuming, and expensive, task.

The most common approach to SOH estimation that is to be met with in industry is based on a parameterisation of a battery model. Such a battery model can be designed on-line in a recursive implementation, for example, such as a Kalman filter. Here the models can be based on the equivalent circuit, or on an electrochemical model.

Equivalent circuit models describe numerous components in order to represent the electrical cell dynamics. Electrochemical models are based on a distribution of the lithium-ion concentration and voltage within the cell, on the basis of coupled partial differential equations.

Here, the accuracy is strongly dependent on the choice of the model used. In addition, the identification and setting of the parameters represents a great challenge, which is often very computationally intensive. Furthermore, with these approaches, a state-of-charge must also be determined simultaneously, which adds to the complexity.

In the recent past, data-based learning approaches have also emerged as an alternative. These are not tied to the choice of a particular physical model.

For example, methods based on Gaussian process regression (GPR) are of known art. These provide an average capacity estimate as well as probabilistic limits, which are based on features such as voltage, current, discharge time, which in turn are calculated from the charge and discharge curves of the cells.

Similarly, so-called support vector machines (SVMs) have provided similar results, using essentially similar parameters.

Neural networks based on autoencoders, such as those from the paper “Li-ion battery health estimation based on multi-layer characteristic fusion and deep learning” by the authors Y. Ding, C. Lu, J. Ma, published in: 2017 IEEE Vehicle Power and Propulsion Conference (VPPC), IEEE, 2017, pp. 1-5, and also the paper “Remaining useful life prediction for lithium-ion battery: A deep learning approach” by the authors L. Ren, L. Zhao, S. Hong, S. Zhao, H. Wang, L. Zhang, published in IEEE Access 6 (2018) 50587-50598, are known to use the autoencoders in order to extract higher-level features from raw charge curve data, and then pass these on to a deep neural network in order to determine an SOH value from the latter.

From the article “An online method for lithium-ion battery remaining useful life estimation using importance sampling and neural networks” by the authors J. Wu, C. Zhang, Z. Chen, published in Applied Energy 173 (2016) 134-140, another method is of known art, in which a deep neural network is trained for a capacity estimation. This involves sampling according to importance from a broad set of input values from charge curves.

In a similar manner, the authors H. Chaoui, and C. C. Ibe-Ekeocha, in their article “State of charge and state of health estimation for lithium batteries using recurrent neural networks” published in the IEEE Transactions on Vehicular Technology 66 (10) (2017) 8773-8783, and the authors A. Eddahech, O. Briat, N. Bertrand, J.-Y. Del’etage, and J.-M. Vinassa, in their article “Behaviour and state-of-health monitoring of li-ion batteries using impedance spectroscopy and recurrent neural networks” published in the International Journal of Electrical Power & Energy Systems 42 (1) (2012) 487-494, propose the use of recurrent neural networks (abbreviated as RNNs).

The disadvantage of previous data-based methods is that they usually require external pre-processing and feature engineering steps. These steps require extensive domain-specific knowledge. In addition, it can be seen that machine learning approaches, such as Gaussian process regression and SVMs, increase in computational complexity with the amount of data to be processed. They are therefore not suitable for use in systems with limited computing and storage performance, such as embedded systems (for example in a battery management system).

While the neural network approaches listed above have no size limitation, they nevertheless require feature extraction steps.

However, approaches based on the recursive neural networks demonstrated above have the property that the learning gradient disappears again after a few (time) steps, by virtue of the character of the short-term memory. To circumvent this, these recursive neural networks use a small number of input features within a few time steps, in order to train the network. However, a small number of input features, as well as a limitation to a few time steps, leads to a decrease in precision.

It should also be noted that parameterised models cannot capture dynamic variations in cell degradation outside of laboratory conditions, that is to say, under real conditions.

In particular, such models require inputs that are impossible, or extremely difficult, to obtain under real conditions.

Data-driven approaches to the modelling of degradation represent a solution to a parameterisation problem, as these approaches are ostensibly not based on a mathematical or an electrical/ electrochemical model, but rather generate parameters from the relationship of input data to desired target data.

To this end a number of approaches have been developed in the past.

One approach is first to model the current state-of-health of the cell from the available inputs, and then to compare this current state-of-health indicator with a predetermined EOL value, in order to determine a measure for the available remaining service life.

However, what these approaches have in common is that they first require a complete back end for the determination of an SOH. In addition, the value determined is only an estimate of the available remaining service life, without, however, the provision of a statement as to how the capacity will develop during the remaining service life. That is to say, the long-term prediction of such models of known art is poor. This could be due to the fact that these models operate only to a limited extent on their own data sets.

Other approaches are based on the iterative prediction of the future of a cell from a certain point in the capacity-cycle progression. It is true to say that these models have the advantage that the prediction mechanism can be determined on the basis of previously determined data. However, these models require that they be executed iteratively until a verification mechanism confirms that the EOL criterion is fulfilled. Moreover, the models are only suitable for deriving relationships between the input and output data of the training data. That is to say, no processing of the parameters on the basis on any future available data is possible. Such an approach can therefore only be used meaningfully in cases where the evolution of the degradation can be assumed to be the same over all time.

Against this background, it is an object of the invention to create an inexpensive, safe and rapid possible approach, with which one or more characteristic values of a battery cell can be provided.

### BRIEF DESCRIPTION OF THE INVENTION

The object of the invention is achieved by means of a method according to Claim 1.

Furthermore, the object is achieved by a device according to Claim 9 for the execution of a method in accordance with the invention.

Further advantageous designs are the subject matter of the dependent claims, the description, and the figures.

### BRIEF DESCRIPTION OF THE FIGURES

In what follows the invention is explained in more detail with reference to the figures. In these:

FIG. 1 shows a family of curves that show the development of the nominal capacity over the number of charging cycles,

FIG. 2 shows a schematic presentation of a system in which forms of embodiment of the invention can be used,

FIG. 3 shows a schematic presentation of a neural network in accordance with aspects of the invention,

FIG. 4 shows a schematic presentation relating to a device in accordance with forms of embodiment of the invention,

FIG. 5 shows a schematic flowchart of exemplary steps for purposes of determining a characteristic value in accordance with aspects of the invention,

FIG. 6 shows a schematic flow chart of exemplary steps for purposes of determining a further characteristic value in accordance with aspects of the invention,

FIG. 7 shows a schematic representation of an exemplary architecture of a network in accordance with an aspect of the invention, and

FIG. 8 shows an exemplary network layer structure of a network in accordance with FIG. 7.

### DESCRIPTION OF THE TYPES OF EMBODIMENT

In what follows the invention is described in more detail with reference to the figures. Here it should be noted that various aspects are described, each of which can be used individually, or in combination. That is to say, any aspect can be used with different forms of embodiment of the invention, unless explicitly represented as a pure alternative.

Furthermore, for the sake of simplicity, only one entity will be referred to in what follows. However, unless explicitly stated, the invention can also in each case comprise a plurality of the entities concerned. In this respect, the use of the word “one” should only be understood as an indication that at least one entity is used in a simple form of embodiment.

Insofar as methods are described in what follows, the individual steps of a method can be arranged and/or combined in any order, insofar as the context does not explicitly indicate otherwise. Furthermore, the methods can be combined with each other, unless explicitly stated otherwise.

Data with numerical values are generally not to be understood as exact values, but rather include a tolerance of between +/- 1 % and +/- 10 %.

References to standards, or specifications, or norms are to be understood as references to standards, or specifications, or norms in force at the time of the filing of the application, and/or, where a priority is claimed, at the time of the filing of the priority application. However, this is not to be understood as a general exclusion of applicability to subsequent or replacement standards, or specifications, or norms.

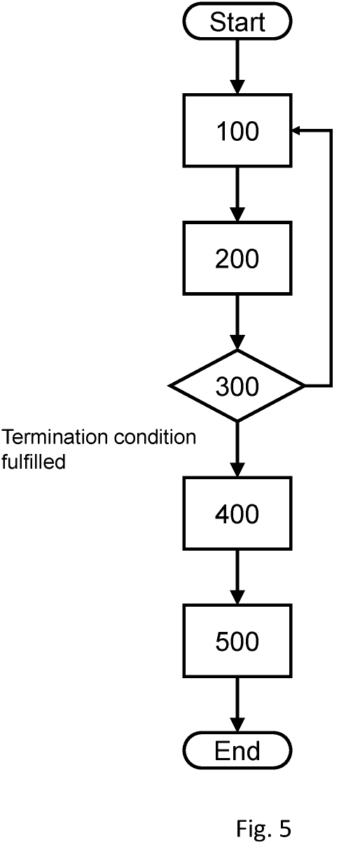

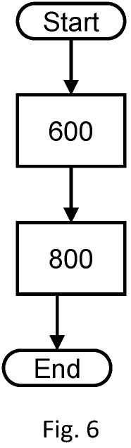

In one aspect of the invention, a method is provided for the local determination of at least one characteristic value of a battery cell, as shown in FIG. 5.

The method outlined in FIG. 5 initially involves a charging process for a battery cell. The battery cell can be composed of a multiplicity of cells. The battery cell can be provided in a vehicle, or can be stationary. The battery cell can be based on a variety of technologies. In particular, the battery cell can be a lithium-based battery cell. By way of example, without being restrictive, the lithium cell can be a lithium-cobalt dioxide accumulator, a lithium-manganese dioxide accumulator, a lithium-iron phosphate accumulator, a lithium-titanate accumulator, or a tin-sulphur lithium-ion accumulator. In particular, the accumulator cell can be a lithium-polymer accumulator. However, other accumulator technologies, such as nickel-, lead-, zinc-, tin-, silicon- or sodium-based accumulator cells, can equally benefit from the invention.

During a normal charging process of the battery cell, a voltage is now determined repeatedly in step 100. A normal charging process means that this does not take place under laboratory conditions, but rather during normal operation. This voltage, or a value representing this voltage, is assigned a time stamp in step 200.

Voltages and associated time stamps obtained in this way can now be supplied to a neural network NN1 in step 400, either continuously, or only after a termination criterion has been achieved.

As a result, the neural network NN1 provides a (first) indicator SOH in step 500, based on the voltages obtained in step 400 and associated time stamps, wherein the (first) indicator SOH is a measure for the nominal capacitance at the end of the last measured applied voltage.

That is to say, based on the time series and the voltages from step 300, a state-of-health indicator is created with respect to the nominal capacity.

Measurements are only taken during the charging process, as the inventors are aware that this can already provide essential information that can be relevant for the service life estimation, that is to say, for the discharging process. At the same time the invention makes use of the fact that the charging process is usually a controlled process, and thus follows a predetermined pattern.

In one form of embodiment of the aspect, the charging process has a predetermined constant current. When a predetermined target voltage is reached, the charging process can be continued with a predetermined voltage, wherein the charging process terminates when the current falls below a predetermined minimum charging current.

This means that the process can be seamlessly integrated into traditional charging processes.

In one form of embodiment of the aspect, the determination of an applied voltage 100, and the assignment 200 to a time stamp, take place under a constant charging current.

This can reduce the amount of training required. In addition, a constant charging current is particularly well suited to the charging of a battery cell such that the latter has a long service life.

In one form of embodiment of the aspect, the neural network NN1 is a long short-term memory (abbreviated as LSTM) network-based neural network.

Before the neural network NN1 is discussed further below, the device 1 will first be examined from a broader systemic perspective.

In the context of the invention, the capacity estimation model can also be separated into two logical parts, an initial training, and also the provision of the model to devices 1 in accordance with the invention.

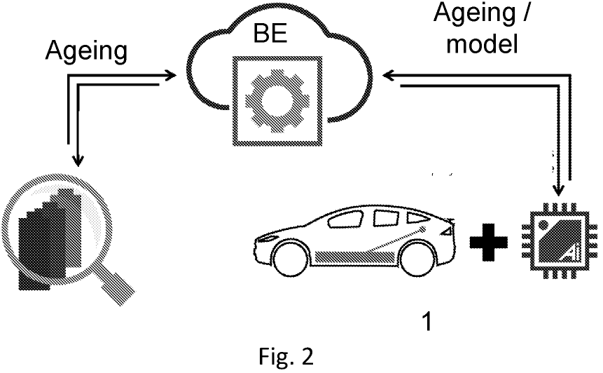

These two parts, and their possible interaction in a system, can be discerned in FIG. 2,

The system in FIG. 2 comprises at least one device 1 in accordance with an aspect of the invention. Furthermore, the system comprises a computation device BE that is remote from the device. Typically, the device 1 is located in the (immediate) vicinity of the battery cell, for example in a vehicle. The remote computation device BE, which can have, for example, more computing power than the device 1, can be, for example, a (cloud) server.

As a rule, the remote computing device BE has access to a similar neural network NN1, NN2.

The neural network NN1, NN2 of the remote computation device BE receives, for example, data from ageing tests of at least one similar (LTSM) cell. These can be used to train the neural network NN1 or NN2.

Furthermore, the neural network NN1, NN2 of the remote computation device BE can also receive determined voltages and time stamps from the at least one device 1.

By this means the neural network NN1 or NN2 can be trained on the remote computation device BE.

The model of the remote computation device BE, thus trained, can then be made available to a neural network NN1, NN2 of one or a plurality of devices 1 for further use.

The communication between the remote computation device BE, the device or devices 1, and any ageing data can be designed so as to be bidirectional.

The exact form of communication, that is to say, whether data / models are requested, or are made available without being requested, can be selected appropriately. That is to say, the communication can be designed to be uni-directional (e.g. ageing data to the remote computation device BE) or bi-directional (remote computation device BE to the device 1). Here various forms of interface can also be used.

Typically, ageing data are first collected experimentally. These are used to train a neural network NN1, NN2 on a remote computation device BE. The trained (best) model is then made available to the device(s) 1. Each device 1 can likewise make its data, which is ultimately also ageing data, available in turn to the remote computation device BE, so that the neural network NN1 or NN2 can be trained further on the remote computation device BE. Thus, the database for the neural network NN1 or NN2 becomes ever larger, and the neural network NN1, NN2 can be further improved. A model of the neural network NN1, NN2 improved in this manner can then in turn be passed on to one or a plurality of devices 1, or requested by them as required.

That is to say, while the hardware requirements for a remote computation device BE are rather high, the hardware and performance requirements for the devices 1 can be very low, so that embedded devices can also be used, or existing hardware, such as is present in battery management systems, can also be used.

The neural network NN1 is preferably a so-called long short-term memory network-based neural network, which can be used in methods of the invention for the determination of at least one characteristic value of a battery cell, in particular a capacity. Such long short-term memory network-based neural networks are also abbreviated as LSTM.

Unlike regression-based methods, linear methods, or Gaussian methods, which require feature extraction, and thus a considerable amount of domain-specific knowledge, so-called deep-learning models are suitable for extracting the corresponding features directly and efficiently from the raw data.

Here a major advantage is that LSTM-based neural networks NN1 can also work with different input sizes, that is to say, input vectors of different sizes, whereas in other methods, for example, these are limited to a fixed size. However, with increasing ageing / number of charge/discharge cycles, the number of values decreases.

The training of a neural network NN1, NN2 is based on so-called back-propagation. Neural network layers contain a non-linear activation function that produces an output for each hidden node in the neural network layers, after receiving the weighting values that are associated with the nodes and the input.

The neural network NN1, NN2 learns during the training phase by altering these node weightings so that the activation function provides values that match well with the training data provided. A determinable limit can be provided for the matching process.

This alteration of the node weightings is accomplished by back-propagation, in which the output of the neural network NN1, NN2 is compared with the target value, and an error is determined. Typically, a cost function, which is also called a loss, is used for this purpose. The cost function can be chosen appropriately. The error value / error vector is then propagated back through all nodes of the neural network NN1, NN2. A so-called optimiser function uses the error to improve the weighting of the neural network NN1, NN2, so that after each successful training step the neural network NN1, NN2 provides better results.

In the case of recursive neural networks, back-propagation is called back-propagation in time. In the latter, the neural network is unfolded in the forward direction in time, and the loss is determined for each time step. The loss gradients are then transmitted in the backward direction with respect to each parameter. The gradients are then used to improve the divided vector w over all time steps, using the optimiser function. LSTM-based neural networks represent modifications of standard cells of a recurrent neural network. In addition to each cell state for each time step, they have a “hidden” memory state, thereby providing a longer memory.

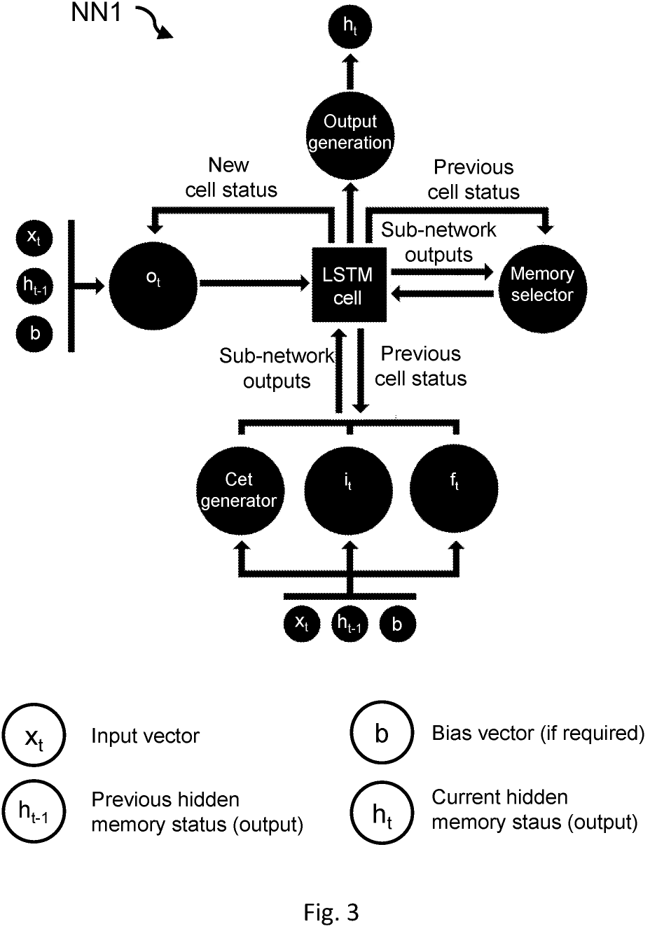

FIG. 3 shows an overview of the architecture of an LSTM cell. This can be viewed as a network that receives inputs and unfolds them over time, learning at each step of the input series. In what follows, σ and tanh are used for the sigmoidal and hyperbolic tangent activation functions, respectively. The different weighting matrices are denoted as w. The input / input vector to a time step is denoted as xt. ht and ht-1 denote the “hidden” memory statuses of a cell at the time step, and at the previous time step t-1, respectively. Ct-1 denotes the previous memory status of the cell, Cet denotes the new memory status of the cell just created, and Ct denotes the current memory status of the cell. The (*) operator denotes an element-related multiplication. Three gates are provided: the input gate it, the forget gate ft, and the output gate ot. Furthermore, two generator circuits are made available; the new memory Cet generator and the “hidden” memory status ht.

$$\text{ft} \text{=} \text{σ} \left(\text{wf} \left[\text{ht-1} \text{,xt}\right] + \text{bf}\right) \qquad \text{(1)}$$

$$\text{it} \text{=} \text{σ} \left(\text{wi} \left[\text{ht-1} \text{,xt}\right] + \text{bi}\right) \qquad \text{(2)}$$

$$\text{ot} \text{=} \text{σ} \left(\text{w0} \left[\text{ht-1} \text{,xt}\right] + \text{b0}\right) \qquad \text{(3)}$$

$$\text{Cet} \text{=} \text{tanh} \left(\text{wc} \left[\text{ht-1} \text{,xt}\right] + \text{bc}\right) \qquad \text{(4)}$$

$$\text{Ct} \text{=} \text{ft} * \text{Ct-1+} \text{it} \text{* Cet} \qquad \text{(5)}$$

$$\text{ht} \text{= ot} \text{*} \text{tanh (Ct)} \qquad \text{(6)}$$

The LSTM cell takes the memory status Ct-1 and the output state ht-1 from the previous time step t-1. and takes the input vector xt from the current time step t as input.

The forget gate decides which part of the old memory should be forgotten, and pushes a corresponding forget vector ft into the pipeline of the cell.

Three sub-networks are involved in the creation of the new memory for the current time step: The input gate processes the input for the present time step. The second sub-network acts as a generator Cet that creates the new memory for the current time step. The third sub-network acts as a memory selector that uses the outputs of the forget gate ft and the input gate it to decide which part(s) of the old and new memory should be retained as the final cell state Ct.

The output gate generates the current output status vector ot, which is then updated in accordance with the new memory status C in the hidden status generator. The new output status is then obtained, which represents the output for the current time step.

An example of an environment can be constructed as follows, but without being limited to this particular implementation:

An example of an architecture can be provided, for example, using the Python 3 programming language with TensorFlow 1.14 as a back end and the Keras deep learning library for layer creation. The LSTM-RNN cell can here be integrated in a bidirectional wrapper, which allows the network to be processed twice, once in the forward direction and once in the backward direction. The backward direction can be used for additional context and feature recognition during training.

The “Adam” optimiser (see D. P. Kingma, J. Ba, Adam: A method for stochastic optimisation (2014), URL htp://arxiv.org/pdf/1412.6980v9), which can be used to train the network, is an adaptive learning method that calculates an individual learning rate for each parameter in the network.

“Adam” provides a very efficient training process. This is particularly noticeable when it is coupled with one (or a plurality of) momentum parameters. For example, the first and second momentum of the error gradient can be used to update the learning rates of each parameter of the network individually. This makes the training even more efficient.

The network loss can be defined, for example, as the mean absolute error. This provides a good performance for regression-based networks.

Other so-called hyper-parameters can be chosen appropriately. For example, the number of time steps can (initially) be 250. The learning rate can, for example, be 0.0001. The validation split can, for example, be set to 20 %, and the dropout to 30 %. The minibatch size can, for example, be 1900 samples.

Regularisation can be implemented in the neural networks of a dropout layer. By this means a specific probability can be assigned to each account, with which an account can be excluded from the training for the current time step. This allows an improvement of the generality of the network, while it reduces the probability of an over-matching of the network to the training data.

A bi-directional LSTM network with 4 layers and 50 nodes per layer has proved to be a good example of a trained network. Here a training loss of about 0.94 % could be realised.

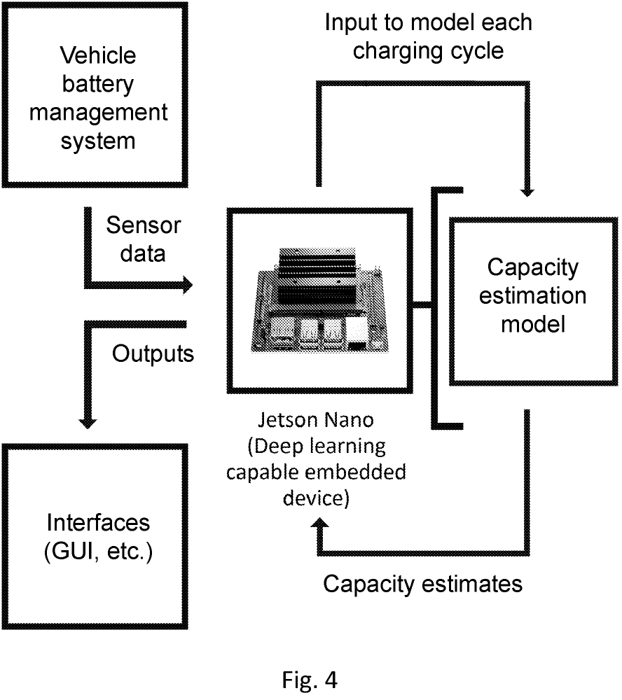

For purposes of validation, a processor-in-the-loop system based on an Nvidia Jetson Nano was implemented (see also FIG. 4). This represents a device 1 in accordance with the invention. The latter provides a small on-board computer that is suitable for machine learning and deep learning applications. As shown in FIG. 4, sensor values, for example from a battery management system (of a vehicle), can be obtained.

In accordance with another aspect of the invention, a further method is also provided. This is based, for example, on time series of voltages and time, as previously described in the context of the first method (steps 100-500), and/or on another measure of a state-of-health indicator SOH of a cell. These time series of voltages and time, as previously described in the context of the first method, or another measure of a state-of-health indicator SOH of a cell, are supplied to a further neural network NN2 in step 600.

The other neural network NN2 is a neural network that is designed for sequence-to-sequence deep learning.

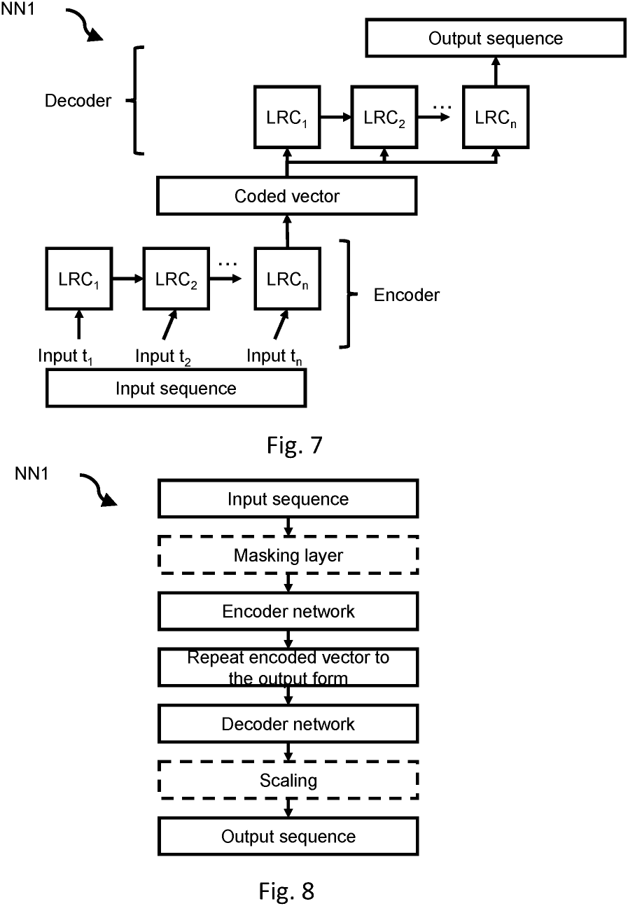

Such a neural network NN2 is shown as an example in FIG. 7, and in the network layers in FIG. 8.

The neural network NN2 can, for example, consist of n = 4 cells (for both the decoder and the encoder). The cells can have as a hidden dimension size, the size of the desired output sequence, for example, 108 nodes for the encoder, and 78 accounts for the decoder. The neural network NN2 can once again be trained, as previously described, with an optimiser, for example “Adam”, for example using the mean absolute error. The input sequence represents a past capacity series, while the output sequence represents a future capacity series.

Optionally, a masking layer can be included to disguise the addition of zero values. Likewise, a scaling layer can optionally be provided to adapt the size of the output sequence to the input sequence.

A second indicator is obtained from the further neural network NN2 in step 800, wherein the second indicator is a further measure of the anticipated degradation of the cell.

In one form of embodiment of the aspect, determined voltages and time stamps of a charging process are in each case stored as a time series, wherein the multiplicity of time series of different charging processes are supplied to the further neural network NN2.

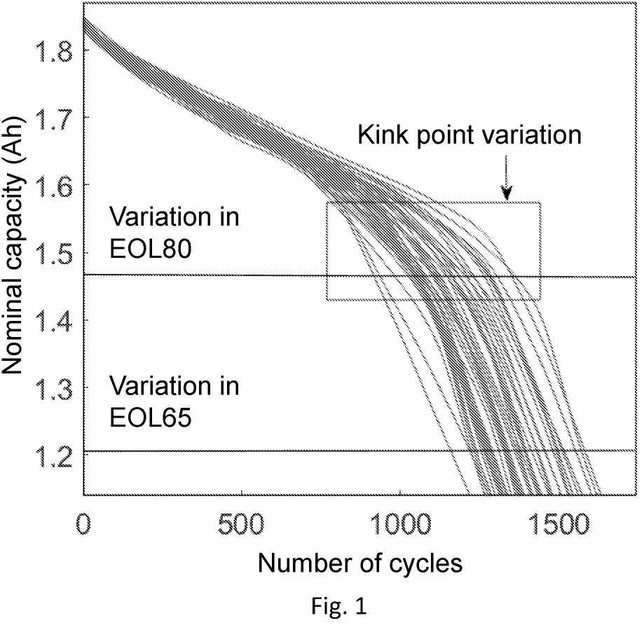

In one form of embodiment of the aspect, the second indicator is the kink point in the degradation. From the determination of the kink point, it can reliably be determined when the ageing accelerates. If the nominal capacity decreases only slowly up to the kink point (at approximately EOL80, corresponding to an 80% nominal capacity), the capacity loss becomes more severe from the kink point. In the case of the curves shown in FIG. 1, for example, the end-of-life EOL is reached at approximately 65% of the nominal capacity (shown in the figure as EOL65). Depending on the onset of the more severe ageing (kink point), this results in approx. 1300-1800 cycles.

Alternatively or additionally, the second indicator can also be a direct measure of the anticipated end-of-life EOL of the cell.

Without limiting the generality, the invention can also be embodied in a device 1 for the execution of one or a plurality of the methods described above. The device 1 can be an embedded system as described above, but it can also be directly integrated into a battery management system, or into a vehicle. Without any limitation of the generality, the system can also be provided on a higher performance (cloud) server, for example a remote computation device BE, on which the training of the neural network(s) NN1, NN2 is provided, which is then made available, for example, to a device 1 in the vicinity of the cell.

In particular, the invention can be used with a lithium-based battery cell.

A particular advantage is that only input data that do not require any further parameterisation, filtering, feature extraction, etc. are required for the training of the model.

Furthermore, the invention can readily be provided in power saving devices 1. Here computation times of less than 2 seconds can be achieved.

Furthermore, different input lengths of time-voltage series can be processed, which increases the flexibility as well as the robustness. In particular, it is also possible to work with incomplete time-voltage series, without this having a lasting effect on the precision. The methods are also robust against any interference.

What is claimed is:

1. A method for the local determination of at least one characteristic value of a battery cell, wherein time series of voltages and time, or another measure of a state-of-health indicator of a cell, measured during normal operation, are supplied to a neural network, wherein the neural network is a network that is designed for sequence-to-sequence deep learning, obtainment of an indicator from the neural network, wherein the indicator is a further measure of the anticipated degradation of the cell, wherein the indicator is determined from the history of the nominal capacity of the battery cell.

2. The method according to claim 1, wherein determined voltages and time stamps of a charging process are in each case stored as a time series, wherein the multiplicity of time series of various charging processes are supplied to the further neural network.

3. The method according to claim 1, wherein the indicator is the kink point in the degradation.

4. The method according to claim 1, wherein the indicator is a measure of the anticipated end of life of the cell.

5. The method according to claim 1, further comprising the steps: during a charging process of the battery cell, repeated determination of an applied voltage and assignment to a time stamp, supply of the determined voltages and time stamps to a neural network, obtainment of an indicator from the neural network, wherein the indicator is a measure of the nominal capacity at the end of the last measured applied voltage.

6. The method according to claim 5, wherein the charging process has a predetermined constant current, wherein when a predetermined target voltage is reached, the charging process is continued at a predetermined voltage, wherein the charging process terminates when the charging current falls below a predetermined minimum charging current.

7. The method according to claim 5, wherein the determination of an applied voltage and assignment to a time stamp takes place during a constant charging current.

8. The method according to claim 1, wherein the neural network is a long short-term memory network-based neural network.

9. A device for the execution of a method according to claim 1.

10. A system comprising:
at least one device configured to make a local determination of at least one characteristic value of a battery cell, wherein the at least one device is further configured to supply to a neural network a time series of voltages and time, or another measure of a state-of-health indicator of a cell, measured during normal operation, wherein the neural network is a network that is designed for sequence-to-sequence deep learning, wherein the at least one device is further configured to obtain an indicator from the neural network, wherein the indicator is a further measure of the anticipated degradation of the battery cell, wherein the indicator is determined from the history of the nominal capacity of the battery cell; and
a remote computation device, wherein the remote computation device comprises a similar neural network, wherein the neural network obtains data from ageing tests of at least one similar cell. and from determined voltages and time stamps, wherein a model of the remote computation device, thereby trained, is made available to a the neural network of the at least one device.

11. Use of a device according to claim 10 with a lithium-based battery cell.

12. Use of a neural network, which is designed for sequence-to-sequence deep learning. in a method for the determination of at least one characteristic value of a battery cell.
